(19) United States
(12) Patent Application Publication
(10) Pub. No.: US 2006/0124592 A1
(43) Pub. Date: Jun. 15, 2006

(54) Chemical mechanical polish slurry

(76) Inventors: Anne E. Miller, Portland, OR (US); Michael D. Klug, Beaverton, OR (US); A. Daniel Feller, Portland, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/009,162

(22) Filed: Dec. 9, 2004

(51) Int. Cl. C09G 1/02; C09K 3/14; C09K 13/00; H01L 21/461; B44C 1/22; C23F 1/00

(52) U.S. Cl. 216/88; 51/307; 51/308; 51/309; 106/3; 252/79.1; 216/89; 438/692

(57) ABSTRACT

Relatively large oxide particles formed during the CMP process can scratch a conductive material being polished. An interference agent is added the polishing slurry, which results in significant reduction in scratching of the conductive material by interfering with the formation of the large oxide particles. The interference agent may comprise materials such as anionic surfactants or reactive silanol agents.

### BACKGROUND OF THE INVENTION

1. Field of the Invention

An embodiment of the present invention relates to microelectronic device fabrication. In particular, an embodiment of the present invention relates to improved polishing slurries for the formation of interconnects.

2. State of the Art

The microelectronic device industry continues to see tremendous advances in technologies that permit increased integrated circuit density and complexity, and equally dramatic decreases in power consumption and package sizes. Present semiconductor technology now permits single-chip microprocessors with many millions of transistors, operating at speeds of tens (or even hundreds) of MIPS (millions of instructions per second), to be packaged in relatively small, air-cooled microelectronic device packages. These transistors are generally connected to one another or to devices external to the microelectronic device by conductive lines and vias (hereinafter collectively referred to “interconnects”) through which electronic signals are sent and/or received.

In a typical interconnect fabrication process, as shown in FIGS. 9-14, a photoresist 202 is patterned on a dielectric material layer 204, as shown in FIG. 9. The dielectric material layer 204 is etched through the photoresist material 202 patterning to form a hole or trench (hereinafter “opening 206”) extending to at least partially through the dielectric material layer 204, as shown in FIG. 10. The photoresist material 202 is then removed and an underlayer(s) 208 is deposited within the opening 206 on sidewalls 210 and a bottom surface 212 thereof, as shown in FIG. 11. The underlayer(s) 208 may be used to improve the adhesion of the dielectric material layer 204 to a conductive material, which will be subsequently deposited, to prevent the conductive material from migrating into the dielectric material layer 204, and/or to act as a seed layer for the conductive material, as will be understood to those skilled in the art. The underlayer(s) 208 also extends proximate a first surface 214 of the dielectric material layer 204.

As shown in FIG. 12, the opening 206 (shown in FIG. 11) is then filled, such as by electroplating, physical vapor deposition, and plasma assisted sputtering, with the conductive material to form a conductive material layer 218. As with the underlayer(s) 208, excess conductive material may form proximate the dielectric material layer first surface 214. The resulting structure is planarized to remove any material that is not within the opening 206, usually by a technique called chemical mechanical polish (CMP). The CMP technique involves contacting the conductive material layer 218 with a rotating polishing pad 222, as shown in FIG. 13. An abrasive slurry 224, such as alumina or silica abrasive 226 suspended in an aqueous solution 228 containing a oxidizer and a chelating agent, is disposed between the polishing pad 222 and the conductive material layer 218, as will be understood to those skilled in the art. The conductive material layer 218 is oxidized by the oxidizer to form an oxide/hydroxide film 232, wherein the oxide/hydroxide film 232 is removed by the abrasives in the abrasive slurry 224. As shown in FIG. 14, the CMP process removes the conductive material layer 218 and underlayer(s) 208 that are not within the opening 206 (see FIG. 9) to form the interconnect 244.

Aluminum and alloys thereof, when used for the conductive material layer 218, are relatively soft materials that are susceptible to scratching. However, its oxide, Al₂O₃ or alumina, is relatively hard and adheres tightly to underlying aluminum. Thus, aluminum oxide is quite difficult to remove without scratching the underlying aluminum. Furthermore, referring back to FIG. 13, when the oxide/hydroxide film 228 (i.e., aluminum oxide/hydroxide film which is generated by the oxidizer in the abrasive slurry 224) is removed, relatively large aggregates 236 (i.e., alumina aggregates) are formed and are dispersed into the abrasive slurry 224. Once in the abrasive slurry 224, the large alumina particles 234 can scratch into the aluminum (i.e.,. conductive material layer 118) and smear it into the dielectric material layer 204, which can ultimately result in shorting between interconnects 244, as will be understood to those skilled in the art. The scratching can also generate severe lines creating a disconnect. A current solution is to the scratching problem is to use a soft polishing pad. However, a soft polishing pad can result in dishing, wherein the aluminum is dug out of the opening 206, as will be understood to those skilled in the art.

Therefore, it would be advantageous to develop chemical mechanical polish slurries which prevent or substantially reduce scratching from aggregated particles during the CMP process.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIG. 1 is a side cross-sectional view of a resist material patterned on a dielectric layer, according to the present invention;

FIG. 2 is a side cross-sectional view of the structure of FIG. 1, wherein an opening is etched into the dielectric layer, according to the present invention;

FIG. 3 is a side cross-sectional view of the structure of FIG. 2, wherein the resist material is removed and at least one underlayer is disposed in the opening, according to the present invention;

FIG. 4 is a side cross-sectional view of the structure of FIG. 3, wherein a conductive material is disposed within the openings and adjacent the underlayer, according to the present invention;

FIG. 5 is a side cross-sectional view of the structure of FIG. 4, wherein the conductive material which in not disposed within the opening is being removed, according to the present invention;

FIG. 6 is a side cross-sectional view of the structure of FIG. 5 after the conductive material not disposed with the opening has been removed, according to the present invention;

FIG. 7 is a bar graph demonstrating aluminum roughness comparing a slurry with no interference agents and slurries with two different interference agents, according to the present invention;

FIG. 8 is a bar graph demonstrating etch rates comparing a slurry with no interference agents and slurries with two different interference agents, according to the present invention;

FIG. 9 is a side cross-sectional view of a resist material patterned on a dielectric layer, as known in the art;

FIG. 10 is a side cross-sectional view of the structure of FIG. 9, wherein an opening is etched into the dielectric layer, as known in the art;

FIG. 11 is a side cross-sectional view of the structure of FIG. 10, wherein the resist material is removed and at least one underlayer is disposed in the opening, as known in the art;

FIG. 12 is a side cross-sectional view of the structure of FIG. 11, wherein a conductive material is disposed within the openings and adjacent the underlayer, as known in the art;

FIG. 13 is a side cross-sectional view of the structure of FIG. 12, wherein the conductive material which in not disposed within the opening is being removed, as known in the art; and

FIG. 14 is a side cross-sectional view of the structure of FIG. 13 after the conductive material not disposed with the opening has been removed, as known in the art.

### DETAILED DESCRIPTION OF THE ILLUSTRATED EMBODIMENT

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

The present invention relates to the addition of an interference agent to a polishing slurry used in a chemical mechanical polish (CMP) process. Relatively large oxide particles formed during the CMP process can scratch in the conductive material being polished and an underlying dielectric material layer. The addition of the interference agent results in significant reduction in scratching of a conductive material by interfering with the formation of these large oxide particles.

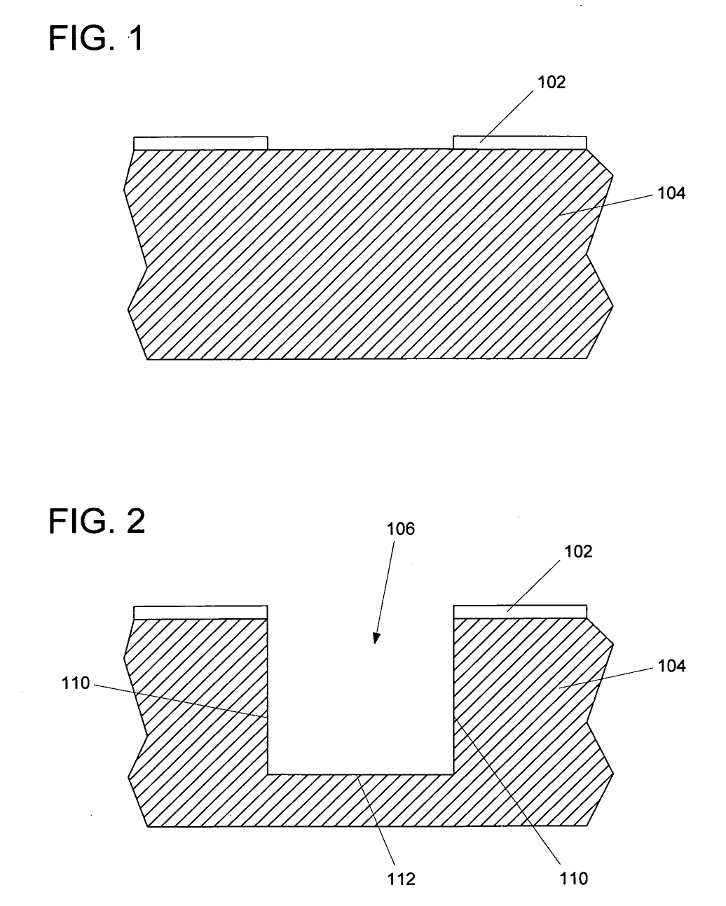

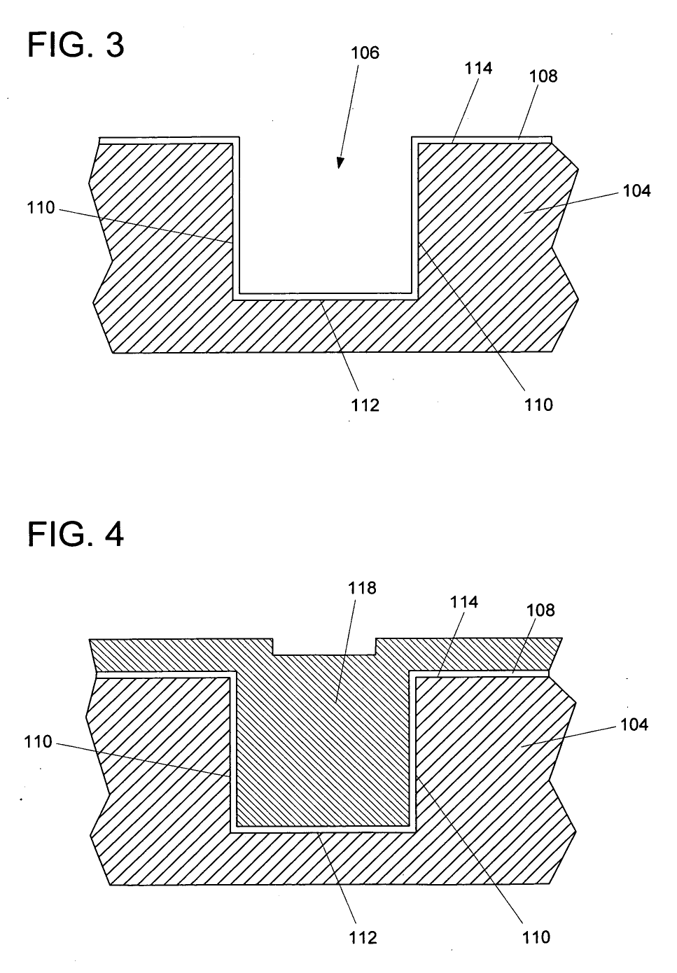

In one embodiment of a fabrication process according to the present invention, as shown in FIG. 1, a photoresist material 102 is patterned on a dielectric material layer 104, such as silicon oxide, carbon doped oxide, and the like. The dielectric material layer 104 is etched through the photoresist material 102 patterning to form a hole or trench (hereinafter collectively “opening 106”) extending to at least partially through the dielectric material layer 104, as shown in FIG. 2. The photoresist material 102 is then removed (typically by an oxygen plasma) and at least one underlayer 108 is deposited within the opening 106 on sidewalls 110 and a bottom surface 112 thereof, as shown in FIG. 3. The underlayer 108 may be used to improve the adhesion of the dielectric material layer 104 to a conductive material, which will be subsequently deposited, to prevent the conductive material from migrating into the dielectric material layer 104, and/or to act as a seed layer for the conductive material. It is, of course, understood that the underlayer 108 may comprise a plurality of layers to achieve any of the listed purposes. In one embodiment of the present invention, at least one of the underlayers 108 may be a nitrogen-containing metal, including, but not limited to tantalum nitride and titanium nitride, and may include a multilayer of HfO₂—TiN—AlTiN—Ti/TiN—Al or variations thereof. The underlayer(s) 108 also extends proximate a first surface 114 of the dielectric material layer 104.

As shown in FIG. 4, the opening 106 is then filled, usually by an electroplating process, with the conductive material (e.g., such as aluminum, titanium, and alloys thereof) to form a conductive material layer 118. As with the underlayer(s) 108, excess conductive material may form proximate the dielectric material layer first surface 114.

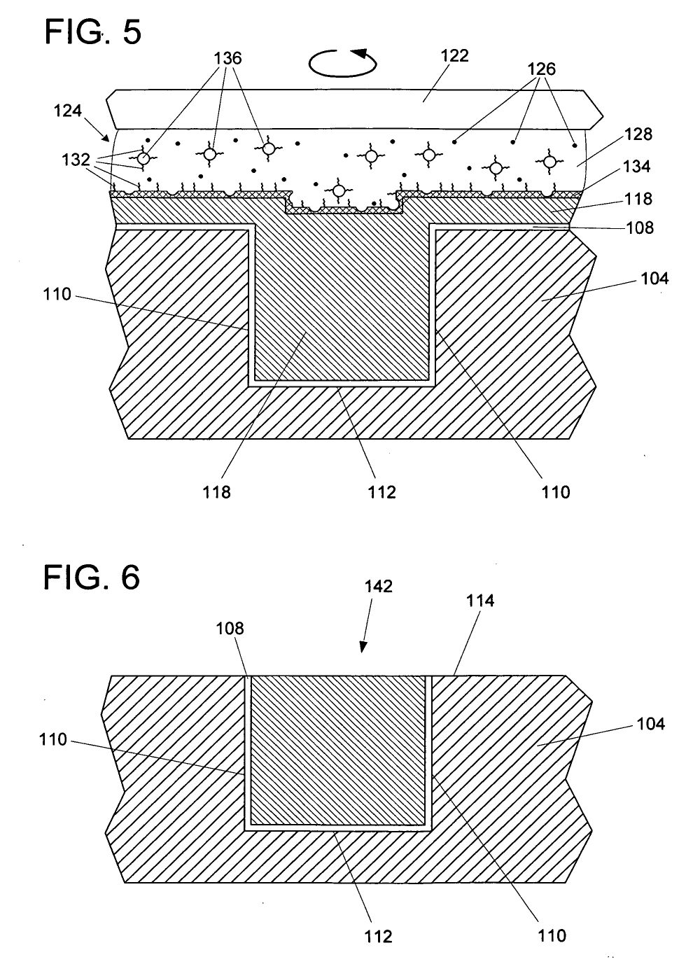

As shown in FIG. 5, the resulting structure is planarized by a chemical mechanical polish (CMP) process to remove any material that is not within the opening 106 (see FIG. 3). The CMP process involves contacting the conductive material layer 118 with a rotating polishing pad 122. An abrasive slurry 124, such as alumina or silica abrasive particles 126 suspended in an aqueous solution 128 containing a oxidizer, a chelating agent, and an interference agent 132 is disposed between the polishing pad 122 and the conductive material layer 118. The conductive material layer 118 is oxidized by the oxidizer (not shown) which forms an oxide/hydroxide film 134 (mixture of oxide and/or hydroxide chemical variants) from the conductive material layer 118, which is removed by the abrasive particles 126 in the abrasive slurry 124. The interference agent 132 is an additive that adheres to any oxide particle aggregates 136 during their formation, which prevents the oxide particle aggregates 136 from growing relatively large. Relatively smaller oxide particle aggregates 136 (i.e., compared to oxide particles aggregates from without an interference agent present) are less susceptible to scratching. In addition, the increase in the number of particles (or an increase in surface area) may be responsible for the higher rates. Furthermore, the interfence agent 132 can interfere with the growth of the oxide/hydroxide film 134 from the conductive material layer 118 by adhering to the surface of the conductive material layer oxide/hydroxide film 134, which also prevents the oxide particle aggregates 136 from growing relatively large, as a thinner film is less likely to have large aggregates pulled therefrom. Thus, the chance of scratching from the oxide particle aggregates 136 is significantly reduced, when an interference agent 132 is used. The concentration of the interference agent may be between about 0.001 and 5.0 wt %, preferably between about 0.01 and 0.1 wt %.

The interference agent 132 may be materials such as anionic surfactants or reactive silanol agents. An examples of the anionic surfactants may include the alkyl sulfate salts of the form R—OSO₃⁻—X⁺ where, R═CₙH₂ₙ₊₁ with n=10-18 and X⁺═NH₄⁺, K⁺, or H⁺. In one embodiment, the anionic surfactant is ammonium lauryl sulfate, C₁₂H₂₅—OSO₃⁻—NH4⁺. For the reactive silanol agents, the chemistry takes the form R′_{y}—Si(OR′)_{z} where y=4−z; R′═CₙH₂ₙ₊₁ and hydrolyzes to form reactive SiOH groups and R′═CₙH₂ₙ₊₁, OCₙH_{2n+1,}CₙH₂ₙ₊₁COOH, CₙH₂ₙOC(O)CH₃, CₙH₂ₙOCH₃, CₙH₂ₙ P(O)(OC₂H₅), or C₂H₄(CH₂NHCH₂)₂NH₂. In one embodiment, the reactive silanol agent is tetraethylorthosilicate, Si(OC₂H5)₄. The adherence of the interference agent 132 to the conductive material layer oxide/hydroxide film 134 can be by anionic or Vanderwaal's forces (primarily with regard to anionic interference agents) and/or by covalent bonding (primarily with regard to reactive silanol interference agents).). It is understood that other interfere agents, such as cationic and non-ionic surfactants, may also reduce the level of scratching during polish, but, in the presence of the silica particles, they can suffer from rate degradation issues. An example of a cationic surfactant is cetyltrimethyl ammonium bromide and an ionic surfactant is polyvinylalcohol.

The CMP process removes the conductive material layer 106 and underlayer(s) 108 that are not within the opening 106 (see FIG. 3) from the dielectric material layer first surface to form the dielectric interconnect 142, as shown in FIG. 6. It will also be understood to those skilled in the art that with the interference agent 132, either a hard or soft polishing pad 122 may be used.

The present invention is particularly useful with aluminum and alloys thereof used as the conductive material layer 106, wherein the oxides thereof are significantly harder than the conductive material (e.g., greater than about 2 times harder). For example, aluminum has a hardness from about 2.0 to 2.9 Mho and aluminum oxide has a hardness from about 8.0 to 9.0 Mho, which makes the present invention particularly application to aluminum and alloys thereof.

In one embodiment, the abrasive slurry may be in a pH range of between about 3 and 7 and may comprise a 0.1 M potassium fluoride aqueous solution having 5% by weight silicon oxide particles (abrasive) and 5.4 grams per liter citric acid (chelating agent). To this abrasive slurry, an interference agent 132 is added. The concentration of the interference agent may be between about 0.001 and 5.0 wt %, in one embodiment between aboutn 0.01 to 0.1 wt %. The interference agent 132 may include, but is not limited to, an anionic surfactant such as ammonium lauryl sulfate, and a reactive silanol agent, such as tetraethylorthosilicate.

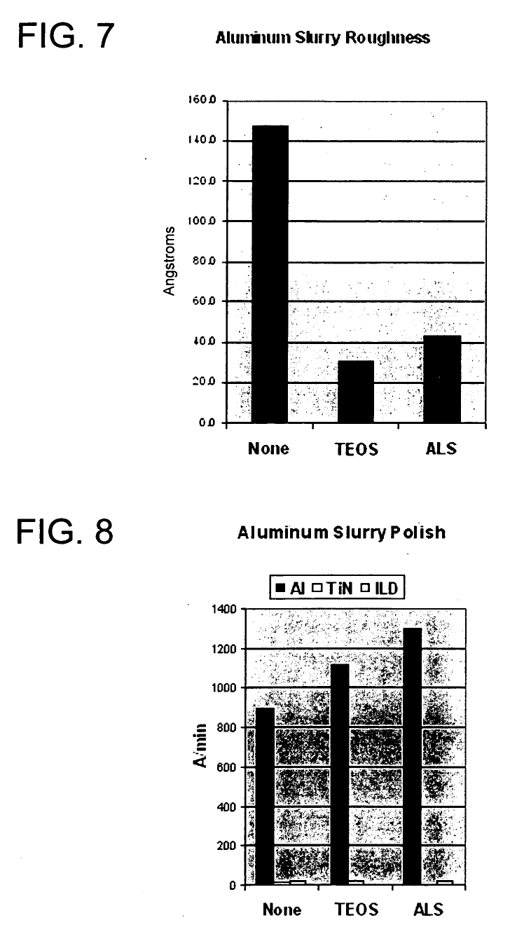

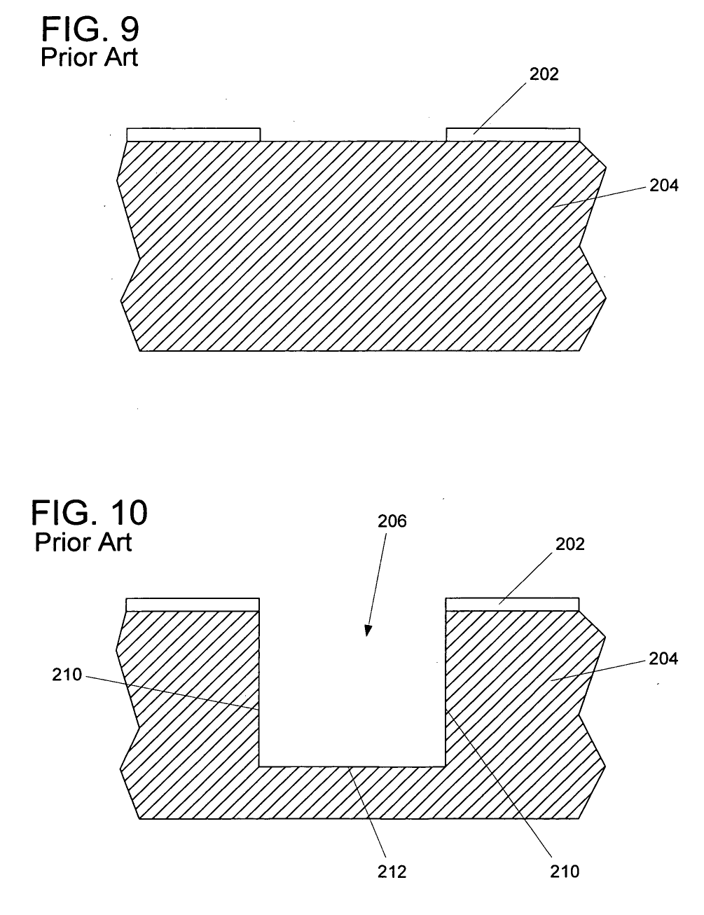

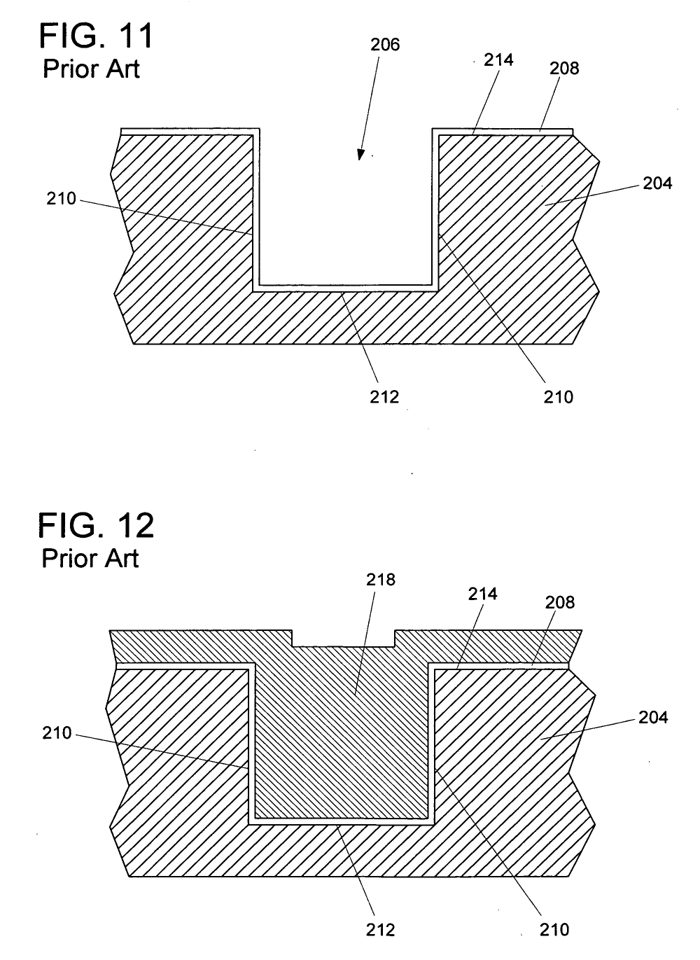

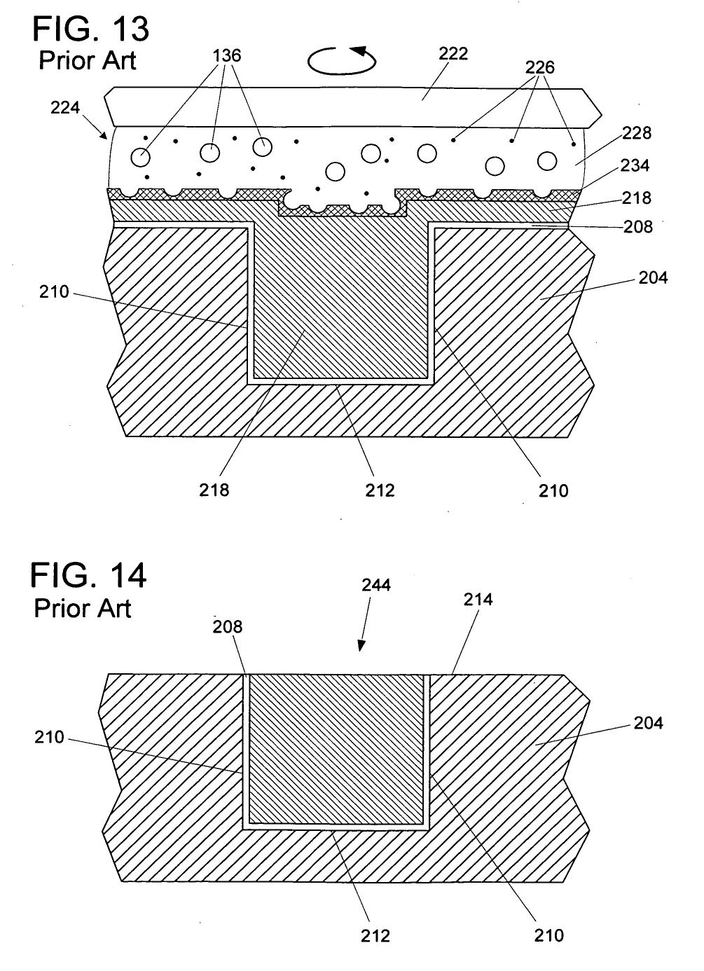

In embodiment used for validation, an 8 inch polish platen was used on 2″ by 2″ coupons with the pressure between the coupons and a IC1020/Suba-IV stacked polishing pad (available from Rodel of Newark, Del., USA) at about 1.5 psi. The speed of rotation of the polishing pad was about 150 rpm. The slurry may be delivered at a rate of about 100 ccm. In an experiment, a slurry as described above was used on aluminum having a titanium nitride underlayer with no interference agent, with tetraethylorthosilicate (TEOS) as the interference agent, and with ammonium lauryl sulfate (ALS) as the interference agent. The results, as shown in FIGS. 7 and 8 (“ILD” is the dielectric material layer), demonstrate a significant improvement in roughness (i.e., less scratching) without a significant degradation in the rate of removal. The surface roughness measurements of FIG. 7 were made with a profilometer across a 100 um scan length and with a probe tip having a radius of curvature of about 0.2 um. In addition to the roughness measurements, samples were observed under a microscope and visual scratching was significantly reduced.

In another embodiment which could be used in production, with a 12 inch wafer in an Applied Materials Reflexion™ Polisher (available from Applied Materials of Santa Clara, Calif., USA), the pressure between a wafer and a IC1020/Suba-IV stacked polishing pad (available from Rodel of Newark, Del., USA) can be between about 0.5 and 2.0 psi. The speed of rotation of the polishing pad may be between about 20 and 60 rpm. The slurry may be delivered at a rate of between about 100 and 300 ccm.

It is, of course, understood that the operating parameters will vary depending on the conductive material layer 118 used, the slurry composition, the equipment used, and the like.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A polishing slurry, comprising:
an abrasive material; and
an interference agent.

2. The polishing slurry of claim 1, wherein said interference agent comprises an anionic surfactant.

3. The polishing slurry of claim 2, wherein said anionic surfactant comprises ammonium lauryl sulfate.

4. The polishing slurry of claim 1, wherein said interference agent comprises a reactive silanol agent.

5. The polishing slurry of claim 4, wherein said reactive silanol agent comprises tetraethylorthosilicate.

6. A polishing slurry comprising:
an abrasive material;
an oxidizer;
a chelating agent; and
an interference agent.

7. The polishing slurry of claim 6, wherein said interference agent comprises an anionic surfactant.

8. The polishing slurry of claim 7, wherein said anionic surfactant comprises ammonium lauryl sulfate.

9. The polishing slurry of claim 6, wherein said interference agent comprises a reactive silanol agent.

10. The polishing slurry of claim 9, wherein said reactive silanol agent comprises tetraethylorthosilicate.

11. The polishing slurry of claim 6, wherein said abrasive comprises silica.

12. The polishing slurry of claim 6, wherein said abrasive comprises alumina.

13. The polishing slurry of claim 6, wherein said chelating agent comprises citric acid.

14. The polishing slurry of claim 6, wherein said polishing slurry is at a pH between about 3 and 7.

15. A method comprising:
providing a conductive material layer disposed on a dielectric material layer and into at least one opening within said dielectric layer;
positioning a rotating polishing pad proximate said conductive material layer;
disposing a polishing slurry between said conductive material layer and said rotating polishing pad, wherein said polishing slurry comprises an abrasive material, an oxidizer, and an interference agent; and
removing a portion of said conductive material layer not within said at least one opening.

16. The method of claim 15, wherein disposing said polish slurry comprises disposing said polishing slurry comprising an abrasive material, an oxidizer, and an anionic surfactant as said interference agent.

17. The method of claim 15, wherein disposing said polishing slurry comprises disposing said polishing slurry comprising an abrasive material, an oxidizer, and an ammonium lauryl sulfate as said interference agent.

18. The method of claim 15, wherein disposing said polish slurry comprises disposing said polishing slurry comprising an abrasive material, an oxidizer, an a reactive silanol agent as said interference agent.

19. The method of claim 18, wherein disposing said polish slurry comprises tetraethylorthosilicate as said reactive silanol agent.
